(19) United States
(12) Patent Application Publication
(10) Pub. No.: US 2018/0190881 A1
(43) Pub. Date: Jul. 5, 2018

(54) PHOSPHOR PLATE ASSEMBLY, LED PACKAGE STRUCTURE, AND METHOD FOR MANUFACTURING LED PACKAGE STRUCTURE

(71) Applicants: LITE-ON OPTO TECHNOLOGY (CHANGZHOU) CO., LTD., CHANGZHOU CITY (CN); LITE-ON TECHNOLOGY CORPORATION, TAPEI CITY (TW)

(72) Inventor: CHEN-HSIU LIN, NEW TAIPEI CITY (TW)

(21) Appl. No.: 15/660,245

(22) Filed: Jul. 26, 2017

(30) Foreign Application Priority Data
Dec. 30, 2016 (CN) 201611262033.9

(51) Int. Cl. H01L 33/50; H01L 33/48; H01L 33/62; H01L 33/60; H01L 25/075; H01L 25/16; H01L 33/54

(52) U.S. Cl. CPC H01L 33/505; H01L 33/486; H01L 33/62; H01L 33/60; H01L 25/0753; H01L 2933/005; H01L 33/54; H01L 2933/0066; H01L 2933/0041; H01L 2933/0058; H01L 25/167

(57) ABSTRACT

An LED package structure includes a substrate, an electrode layer and an insulating layer disposed on the substrate with a coplanar arrangement, an LED chip mounted on the electrode layer and the insulating layer, a phosphor plate covering a top surface of the LED chip, and a reflective housing disposed on the electrode layer and the insulating layer and covering side surfaces of the LED chip and side surfaces of the phosphor plate. An opening is formed on the top surface of the reflective housing so as to expose a light emitting surface of the phosphor plate. A distance between the top surface of the reflective housing and the substrate is greater than a distance between the light emitting surface of the phosphor plate and the substrate. A distance between the top surface of the reflective housing and the light emitting surface is in a range of 10˜30 μm.

### BACKGROUND OF THE INVENTION

### 1. Field of the Invention

The present disclosure relates to an LED; in particular, to a phosphor plate assembly, an LED package structure, and a method for manufacturing an LED package structure.

### 2. Description of Related Art

The conventional LED package structure is formed by filling a white silicone resin around an LED chip for improving a forward light efficiency thereof, and a mold used for forming the conventional LED package is provided with a release film adhered on an inner bottom surface of the mold for preventing the white silicone resin from adhering onto a light emitting surface of the phosphor plate. However, the release film cannot be entirely adhered to the inner bottom surface of the mold, such that the white silicone resin cannot be filled within the mold entirely. Therefore, the white silicone resin cannot cover entirely the side surface of the LED chip. Furthermore, a cracking problem of a phosphor plate of the conventional LED package structure is also easily occurred when the phosphor plate disposed on the LED chip is received simultaneously in the mold.

### SUMMARY OF THE INVENTION

The present disclosure provides a phosphor plate assembly, an LED package structure, and a method for manufacturing an LED package structure to solve the problem associated with conventional LED package structure.

In the LED package structure of the present disclosure, a reflective housing is formed around at least one light-emitting unit, and a top plane of the reflective housing is higher than a light emitting surface of a phosphor plate in a range of 10 μm˜30 μm, so that an interference generated from the adjacent two light-emitting units can be avoided for effectively increasing a light efficiency of the LED package structure.

Moreover, in the method of the present disclosure, a phosphor plate set is disposed on the LED chip assembly, so that when an insulator assembly and a reflector assembly are formed on the substrate assembly in a mold, a buffer film of the phosphor plate set is compressed and provides a buffer function. Thus, the method can be implemented to prevent various problems from occurring with the LED package structure, including cracking of the phosphor plate, overflowing of the white silicone resin, and gaps between any two adjacent LED chips too small to fill with the white silicone resin.

In order to further appreciate the characteristics and technical contents of the present disclosure, references are hereunder made to the detailed descriptions and appended drawings in connection with the present disclosure. However, the appended drawings are merely shown for exemplary purposes, and should not be construed as restricting the scope of the present disclosure.

### BRIEF DESCRIPTION OF THE DRAWINGS

FIG. 1 is a perspective view showing a step S110 and a step S120 of a method for manufacturing an LED package structure according to the present disclosure;

FIG. 2 is a perspective view showing a step S130 and a step S140 of the method;

FIG. 3 is a perspective view showing a step S141 and a step S142 of the method;

FIG. 4 is a perspective view showing a step S143 of the method;

FIG. 5 is a schematic view showing a step S150 and a step S160 of the method;

FIG. 6 is a perspective view showing a step S170 of the method;

FIG. 7 is a perspective view showing a step S180 of the method;

FIG. 8 is a perspective view showing the LED package structure according to an embodiment of the present disclosure;

FIG. 9 is an exploded view of FIG. 8;

FIG. 10 is an exploded view of FIG. 8 from another perspective;

FIG. 11A is a planar view showing an electrode layer of the LED package structure;

FIG. 11B is a planar view showing the electrode layer of the LED package structure in another configuration;

FIG. 11C is a planar view showing the electrode layer of the LED package structure in yet another configuration;

FIG. 12 is a cross-sectional view taken along a cross-sectional line XII-XII of FIG. 8;

FIG. 13 is an enlarged view showing a portion XIII of FIG. 12;

FIG. 14 is an exploded view showing the LED package structure according to another embodiment of the present disclosure;

FIG. 15 is a planar view showing the electrode layer of FIG. 14;

FIG. 16 is a perspective view showing the LED package structure according to yet another embodiment of the present disclosure;

FIG. 17 is an exploded view of FIG. 16; and

FIG. 18 is a cross-sectional view taken along a cross-sectional line XVIII-XVIII of FIG. 16.

### DETAILED DESCRIPTION OF THE PREFERRED EMBODIMENTS

References are hereunder made to the detailed descriptions and appended drawings in connection with the present disclosure. However, the appended drawings are merely provided for exemplary purposes, and should not be construed as restricting the scope of the present disclosure.

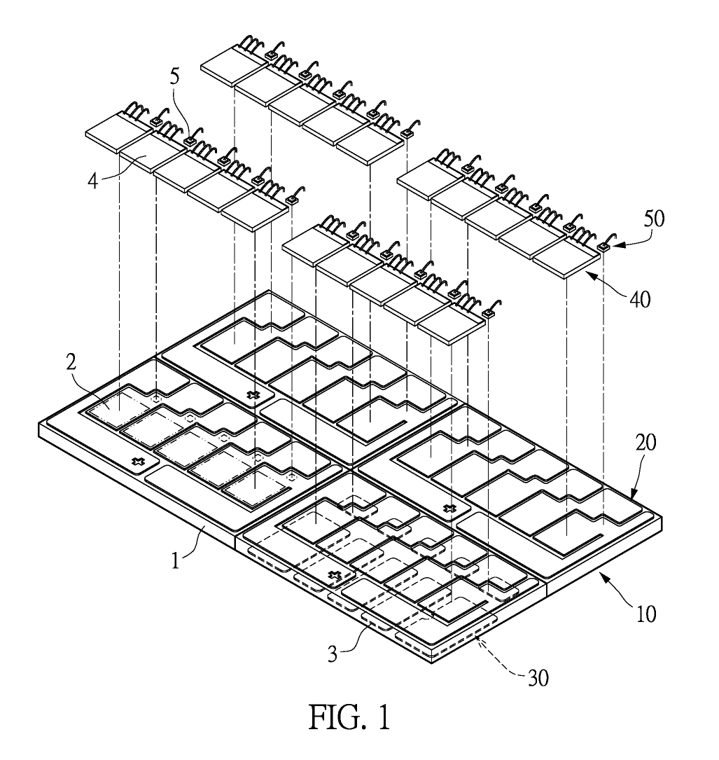

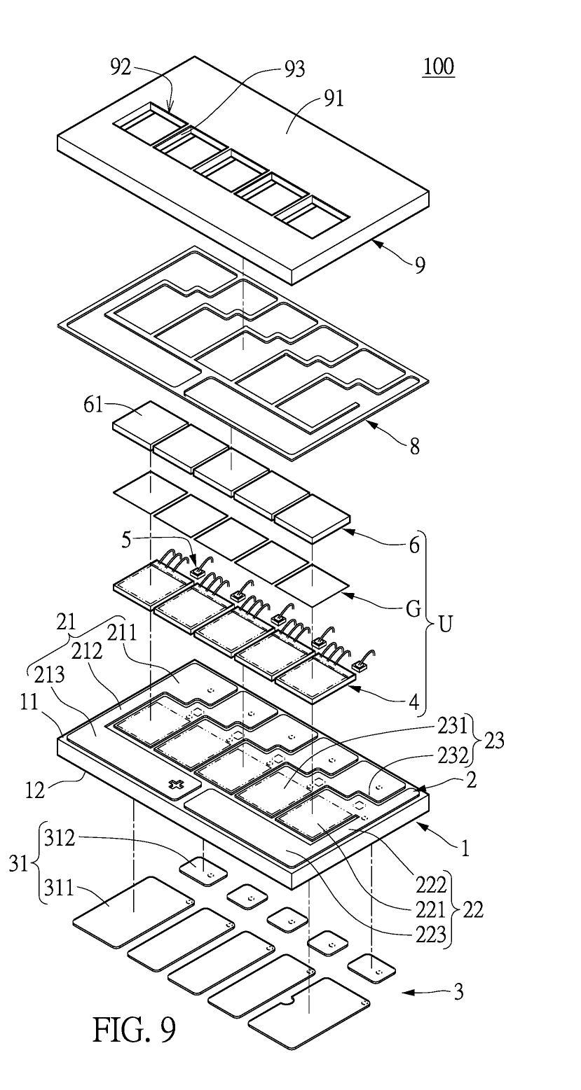

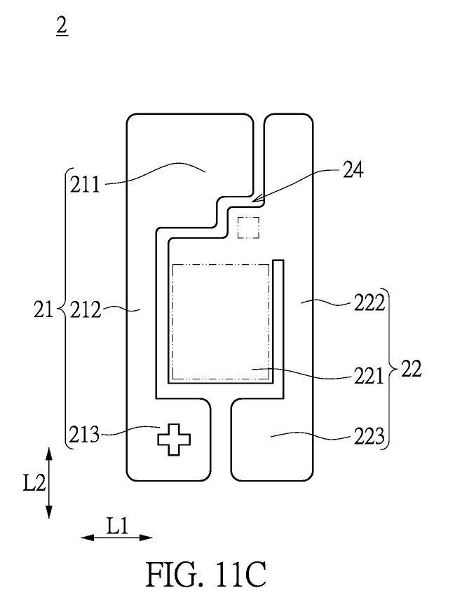

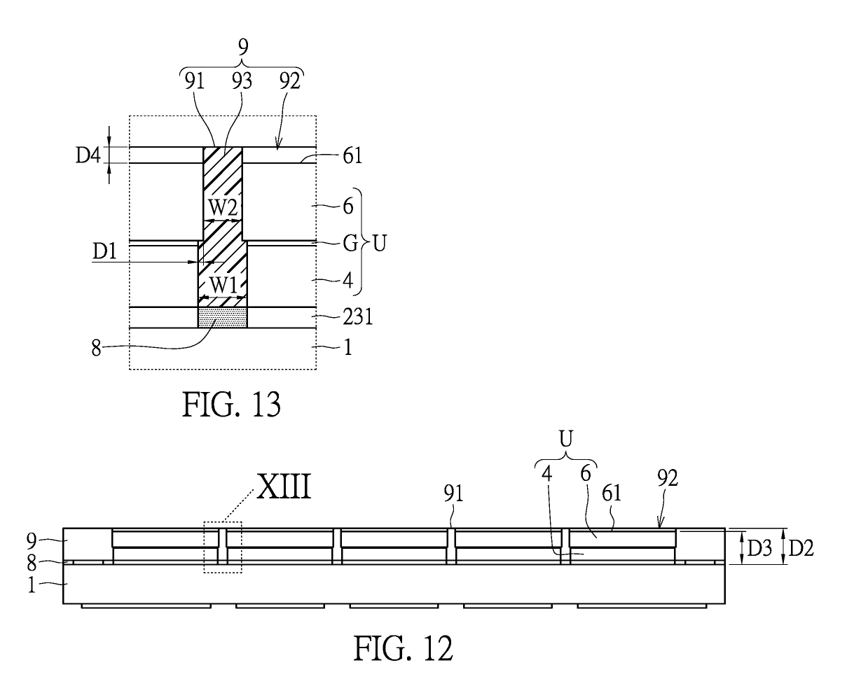

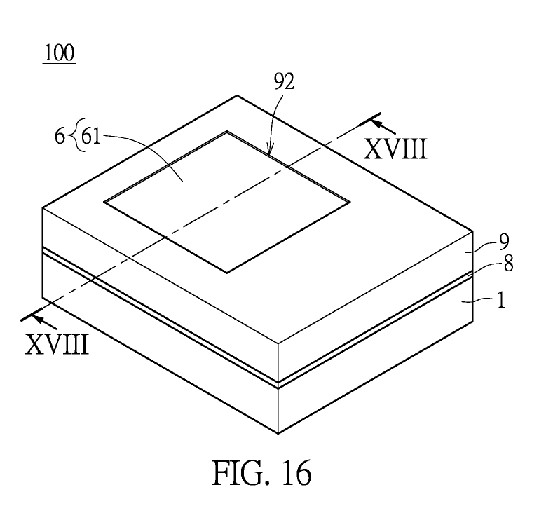

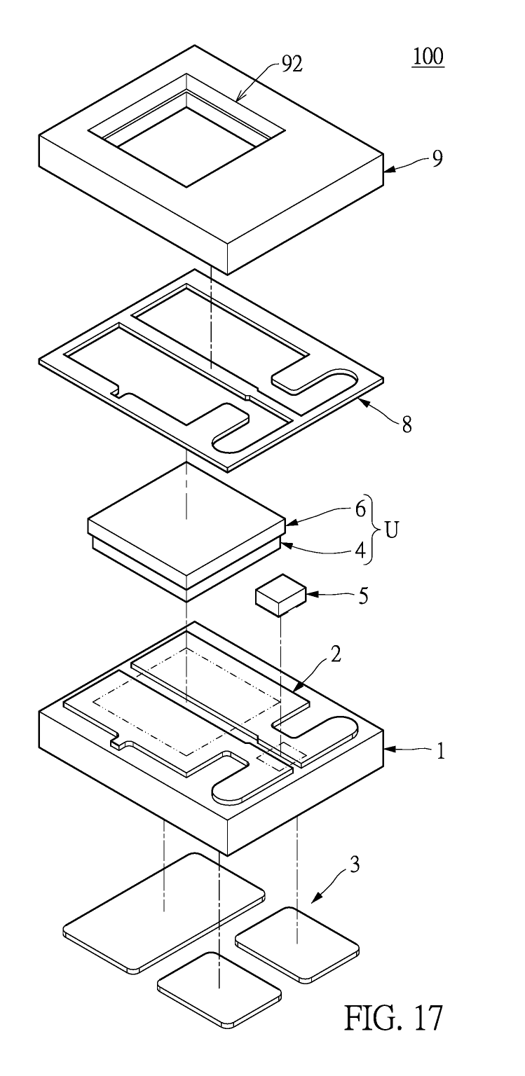

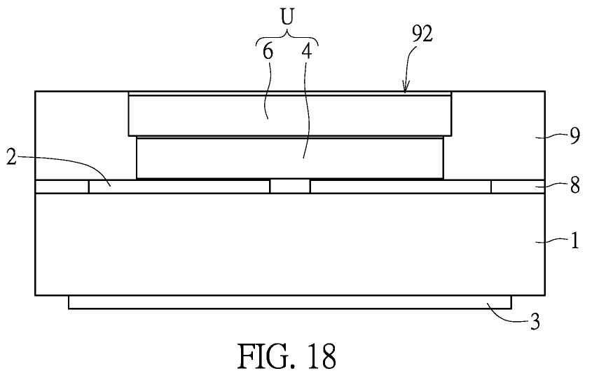

Reference is made to FIGS. 1 to 18, which illustrate the present disclosure. The present disclosure discloses an LED package structure and a method for manufacturing the LED package structure. The following description discloses the method first in order to more clearly explain the LED package structure 100 (as shown in FIG. 8), but the LED package structure 100 of the present disclosure is not limited to being produced by the method.

Reference is made to FIGS. 1 to 7, which show steps S110˜S180 of the method of the present embodiment. The steps can be changed or replaced in a reasonable manner, and the sequence of the steps can be adjusted according to practical needs.

In the step S110 (as shown in FIG. 1), a substrate assembly 10, an electrode assembly 20, and a soldering pad assembly 30 are provided, and the electrode assembly 20 and the soldering pad assembly 30 are respectively disposed on two opposite surfaces of the substrate assembly 10. The substrate assembly 10 can be defined as a plurality of substrates 1. The electrode assembly 20 includes a plurality of electrode layers 2 respectively disposed on the substrates 1 and spaced apart from each other. The soldering pad assembly 30 includes a plurality of soldering layers 3 respectively disposed on the substrates 1 and spaced apart from each other.

In the step S120 (as shown in FIG. 1), an LED chip assembly 40 and a Zener chip assembly 50 are mounted on the electrode assembly 20. The LED chip assembly 40 includes a plurality of LED chips 4 respectively mounted on the electrode layers 2, and each of the LED chips 4 is electrically connected to the corresponding electrode layer 2 and the corresponding soldering layer 3. The Zener chip assembly 50 includes a plurality of Zener chips 5 respectively mounted on the electrode layers 2.

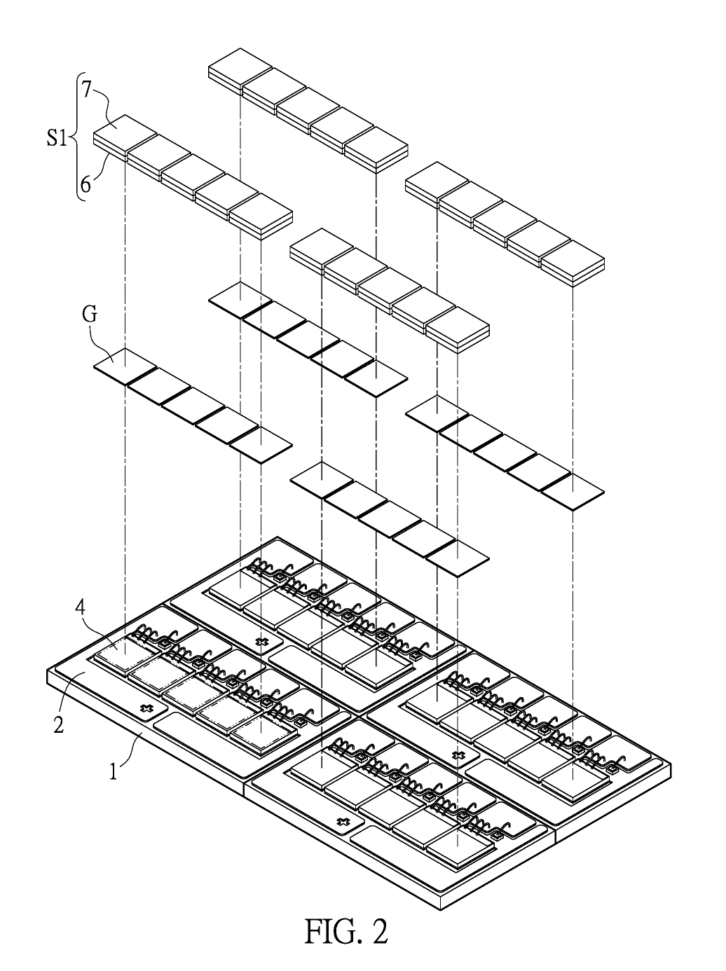

In the step S130 (as shown in FIG. 2), a plurality of transparent adhesive layers G are respectively disposed on the LED chips 4. Each of the transparent adhesive layers G is made of transparent silicone resin and has a thickness, which is preferably smaller than or equal to 10 μm, but the present disclosure is not limited thereto.

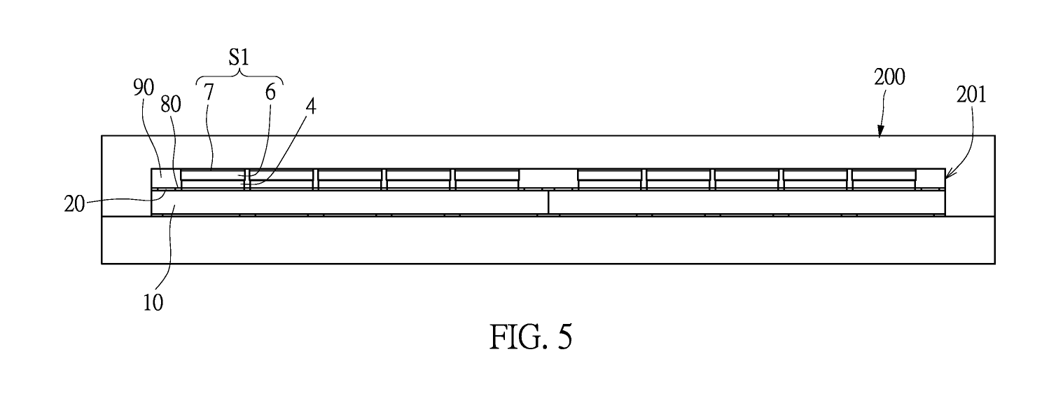

In the step S140 (as shown in FIG. 2), a plurality of phosphor plate sets S1 are taken from a phosphor plate assembly S (as shown in FIG. 4) to respectively adhere to the LED chips 4. Each of the phosphor plate sets S1 includes a phosphor plate 6 and a buffer sheet 7 detachably disposed on the phosphor plate 6. Each of the phosphor plate sets S1 is adhered to the respective LED chip 4 by using one of the transparent adhesive layers G.

Moreover, the method of the present embodiment can further include steps S141˜S143 for preparing the phosphor plate assembly S. The phosphor plate assembly S can be used independently and is not limited to being applied to the method. The steps S141˜S143 of the method are disclosed as follows.

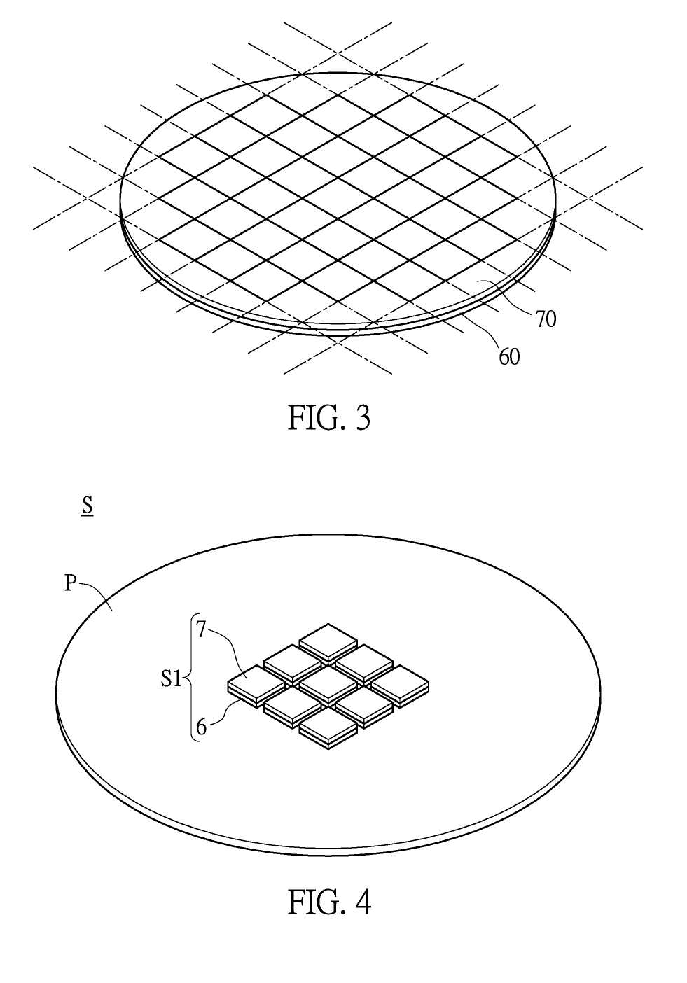

In the step S141 (as shown in FIG. 3), a buffer film 70 is fixed on a phosphor film 60. The buffer film 70 (or each buffer sheet 7) in the present embodiment can be a thermal release tape, a heat-resistant tape, or a UV tape. The buffer film 70 is provided with a sticky and can be compressed by resilient compression.

In the step S142 (as shown in FIGS. 3 and 4), the phosphor film 60 and the buffer film 70 stacked on the phosphor film 60 are sliced to form a plurality of phosphor plates 6 having the same size and a plurality of buffer sheets 7 respectively and detachably disposed on the phosphor plates 6. Each phosphor plate 6 and the respective buffer sheet 7 are defined as the phosphor plate set S1. Specifically, both the phosphor film 60 and the buffer film 70 are sliced simultaneously in each slicing process. Each phosphor plate 6 and the respective buffer sheet 7 have an outer contour substantially in shape corresponding to (e.g., slightly larger than) an outer contour of each of the LED chips 4. That is to say, the phosphor film 60 and the buffer film 70 are sliced according to the outer contour of the LED chip 4, thereby the outer contour of each phosphor plate 6 and the respective buffer sheet 7 are the same with the outer contour of each LED chip 4.

In the step S143 (as shown in FIG. 4), a plurality of the phosphor plate sets S1 are detachably adhered to a carrier P to form the phosphor plate assembly S. The carrier P is convenient for transporting the phosphor plate sets S1. A a position data, which is related to a position of each of the phosphor plate sets S1 with respect to the carrier P, can be provided for an automation equipment (not shown), so that each of the phosphor plate sets S1 can be taken from the carrier P by the automation equipment according to the position data.

Moreover, the structural features of the phosphor plate assembly S are disclosed as follows. The phosphor plate assembly S includes a carrier P and a plurality of phosphor plate sets S1 substantially in a matrix arrangement and detachably adhered to the carrier P. Each of the phosphor plate sets S1 includes a phosphor plate 6 and a buffer sheet 7 detachably disposed on the phosphor plate 6, and side surfaces of the buffer sheet 7 being substantially and respectively aligned with that of the phosphor plate 6.

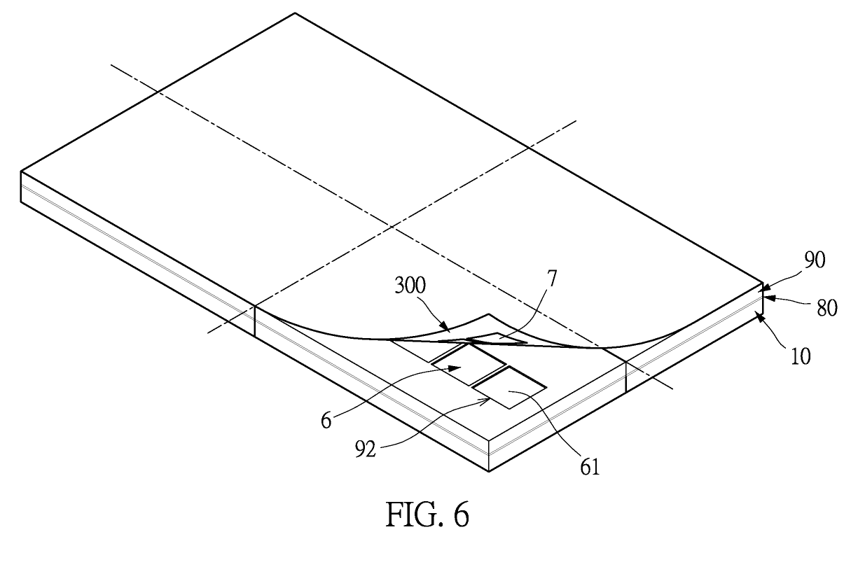

In the step S150 (as shown in FIG. 5), the substrate assembly 10 and the components (e.g., the LED chip assembly 40, the Zener chip assembly 50, and the phosphor plate sets S1) disposed on the substrate assembly 10 are arranged in a cavity 201 of a mold 200, and the buffer sheets 7 are pressed in the cavity 201. Each of the buffer sheets 7 pressed by the mold 200 has a pressing thickness in a range of 10 μm˜30 μm, but the present disclosure is not limited thereto.

In the step S160 (as shown in FIG. 5), a white silicone resin is injected into the mold 200 to fully fill within the cavity 201 so as to form an insulator assembly 80 and a reflector assembly 90 simultaneously. The insulator assembly 80 is shape-complementary to and coplanar with the electrode assembly 20. The reflector assembly 90 is disposed on the insulator assembly 80, and the reflector assembly 90 surrounds and covers the side surfaces of each LED chip 4, the side surfaces of each phosphor plate 6, and the side surfaces of each buffer sheet 7.

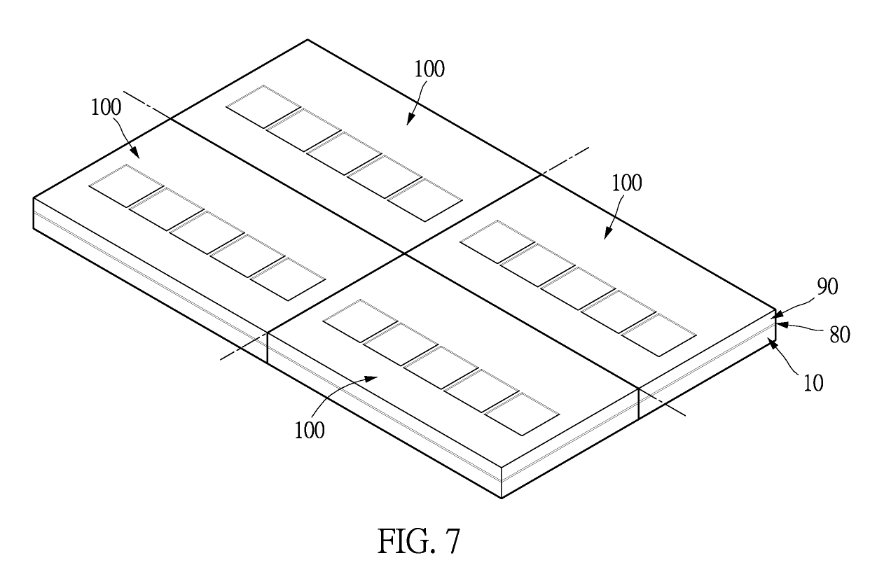

In the step S170 (as shown in FIG. 6), the buffer sheets 7 are respectively removed from the phosphor plates 6 so as to form a plurality of openings 92 recessed on a top surface of the reflector assembly 90, such that light-emitting surfaces 61 of the phosphor plates 6 are exposed. A depth of each of the openings 92 is substantially equal to the thickness of the buffer sheet 7 pressed by the mold 200.

Specifically, a tape 300 is adhered to the buffer sheets 7, and then the tape 300 is torn away to remove the buffer sheets 7 adhered on the tape 300 from the phosphor plates 6. It should be noted that an adhesion between the tape 300 and the buffer sheet 7 is larger than an adhesion between the buffer sheet 7 and the phosphor plate 6.

Moreover, before each buffer sheet 7 is removed from the respective phosphor plate 6, the adhesion between each buffer sheet 7 and the respective phosphor plate 6 can be reduced according to the material of the buffer sheet 7, such as heating the buffer sheet 7, irradiating a UV light on the buffer sheet 7, or moistening the buffer sheet 7 by an organic solution (e.g., an acetone, an ethanone, or an isopropanol, etc.). Thus, each buffer sheet 7 can be removed from the respective phosphor plate 6 more easily.

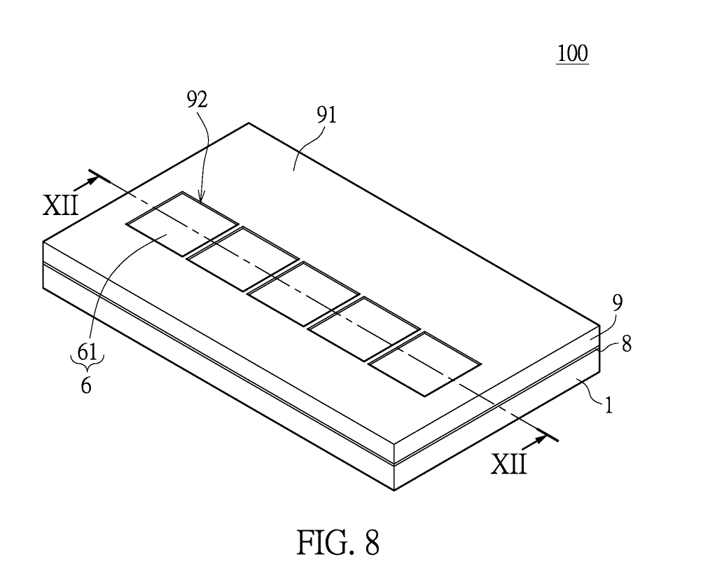

In the step S180 (as shown in FIG. 7), the reflector assembly 90, the insulator assembly 80, and the substrate assembly 10 are sliced to form a plurality of LED package structures 100. Thus, in the method of the present embodiment, the phosphor plate set S1 is disposed on the LED chip 4, so that when the insulator assembly 80 and the reflector assembly 90 are formed in the mold 200, the buffer sheet 7 is compressed and provides a buffering function. Thus, the method can be implemented to prevent various problems from occurring with the LED package structures 100, including cracking of the phosphor plate 6, overflowing of the white silicone resin, and gaps between any two adjacent LED chips 4 too small to fill with the white silicone resin. In the present embodiment, the white silicone resin is provided for forming the insulator assembly 80 and the reflector assembly 90 in a molding process.

The method of the present embodiment has been disclosed in the above description, and the LED package structure 100 is also disclosed in the following description.

Reference is made to FIGS. 8 to 13, which show the LED package structure 100 of the present embodiment. The LED package structure 100 includes a substrate 1, an electrode layer 2, an insulating layer 8, a soldering layer 3, a plurality of LED chips 4, a plurality of Zener chips 5, a plurality of phosphor plates 6, and a reflective housing 9. The electrode layer 2 and the insulating layer 8 are disposed on one surface of the substrate 1, and the soldering layer 3 is disposed on the other surface of the substrate 1. The LED chips 4 and the Zener chips 5 are mounted on the electrode layer 2. The phosphor plates 6 are respectively adhered to the LED chips 4. The reflective housing 9 is disposed on the electrode layer 2 and the insulating layer 8.

In order to clearly explain the present embodiment, each LED chip 4 and the respective phosphor plate 6 are co-defined as a light-emitting unit U. The structure and connection relationships of each component of the LED package structure 100 are disclosed in the following description.

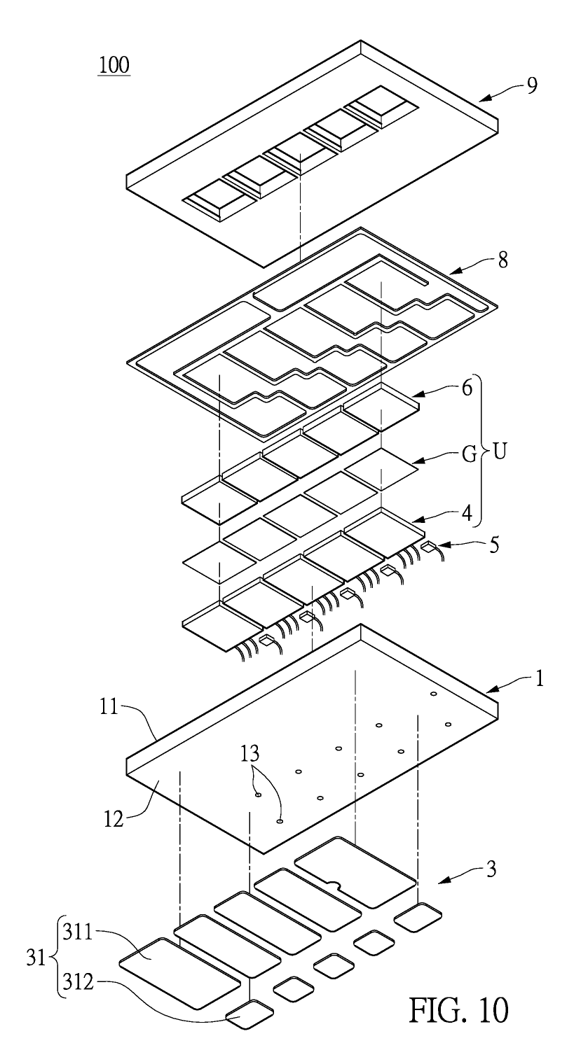

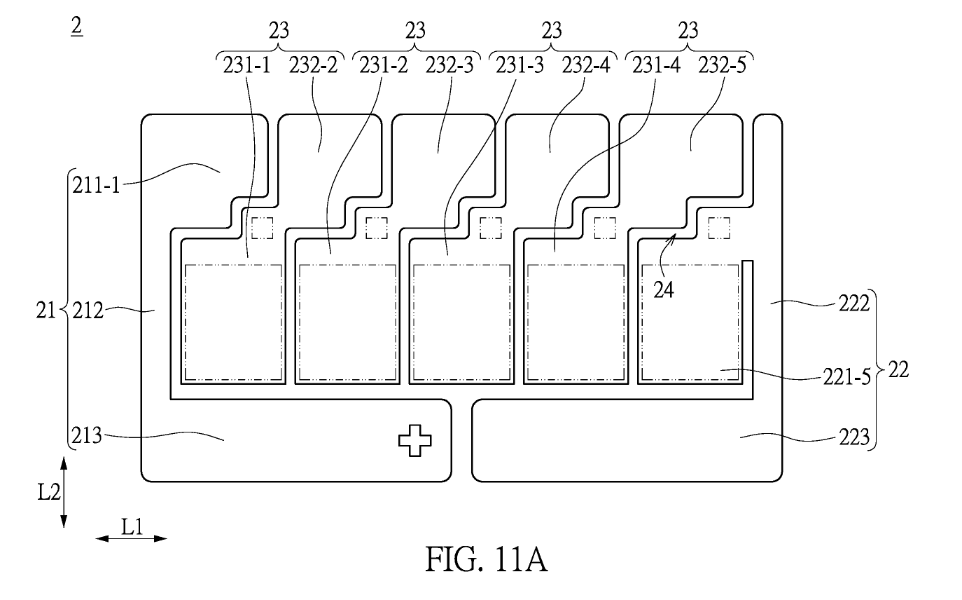

As shown in FIGS. 9 and 10, the substrate 1 has a first surface 11 and a second surface 12 opposite to the first surface 11. The substrate 1 includes a plurality of conductive pillars 13 embedded therein, and two opposite ends of each conductive pillar 13 are respectively exposed from the first surface 11 and the second surface 12.

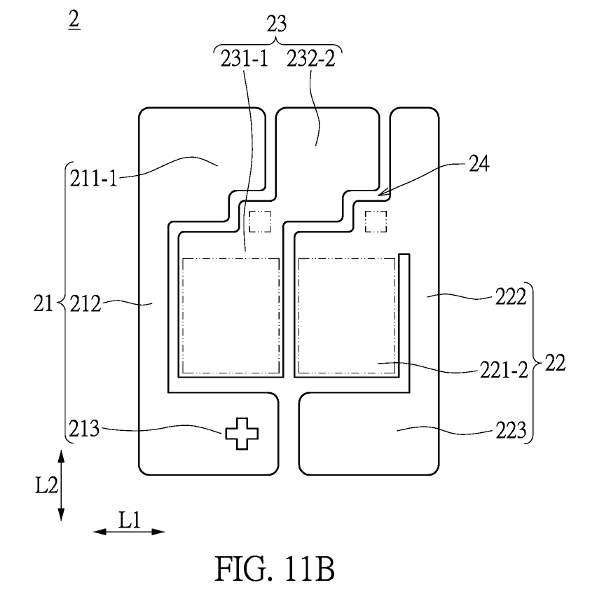

As shown in FIGS. 9 and 11A, the electrode layer 2 is disposed on the first surface 11 of the substrate 1. The electrode layer 2 includes a first metallic pad 21, a second metallic pad 22, and four third metallic pads 23. The four third metallic pads 23 are arranged between the first metallic pad 21 and the second metallic pad 22 in a first direction L1.

The first metallic pad 21 has an L-shaped first wiring portion 211-1, which can also be referred-to as a wiring portion 211, an elongated first extending portion 212, and a rectangular first electrode portion 213. Two opposite ends of the first extending portion 212 are respectively connected to the first wiring portion 211-1 and the first electrode portion 213. The second metallic pad 22 has an L-shaped fifth bonding portion 221-5, which can be named as a bonding portion 221, an elongated second extending portion 222, and a rectangular second electrode portion 223. The second extending portion 222 is connected between the fifth bonding portion 221-5 and the second electrode portion 223. Each of the third metallic pads 23 has an L-shaped bonding portion 231 (i.e., a first bonding portion 231-1, a second bonding portion 231-2, a third bonding portion 231-3, or a fourth bonding portion 231-4) and an L-shaped wiring portion 232 (i.e., a second wiring portion 232-2, a third wiring portion 232-3, a fourth wiring portion 232-4, or a fifth wiring portion 232-5) integrally connected to the bonding portion 231 (i.e., a first bonding portion 231-1, a second bonding portion 231-2, a third bonding portion 231-3, or a fourth bonding portion 231-4). Each of the bonding portion 221-5, 221-1˜221-4 is provided for mounting one of the LED chips 4 and one of the Zener chips 5. Each of the wiring portion 221-1, 232-2˜232-5 is provided for wiring one of the LED chips 4 and one of the Zener chips 5.

Moreover, the first wiring portion 211-1 of the first metallic pad 21 and the second to fifth wiring portions 232-2˜232-5 of the third metallic pads 23 are arranged in one row parallel to the first direction L1 and spaced apart from each other. The fifth bonding portion 221-5 of the second metallic pad 22 and the first to fourth bonding portions 231-1˜231-4 of the third metallic pads 23 are arranged in another row parallel to the first direction L1 and spaced apart from each other.

In other words, the wiring portion 211 of the first metallic pad 21 in the present embodiment can be defined as the first wiring portion 211-1, and the other wiring portions 232 of the third metallic pads 23 in the present embodiment can be sequentially defined as the second wiring portion 232-2 arranged adjacent to the first wiring portion 211-1, the third wiring portion 232-3, the fourth wiring portion 232-4, and the fifth wiring portion 232-5. Moreover, one of the bonding portions 231 of the third metallic pad 23 in the present embodiment, which is arranged away from the bonding portion 221 of the second metallic pad 22, can be defined as the first bonding portion 231-1. The other bonding portions 231, 221 in the present embodiment can be sequentially defined as the second bonding portion 231-2, the third bonding portion 231-3, the fourth bonding portion 231-4, and the fifth bonding portion 221-5.

The first wiring portion 211-1 and the first bonding portion 231-1 are arranged in a second direction L2 perpendicular to the first direction L1, and a gap 24 having at least one corner is formed between the first wiring portion 211-1 and the first bonding portion 231-1. The second wiring portion 232-2 and the second bonding portion 231-2 are arranged in the second direction L2, and a gap 24 having at least one corner is formed between the second wiring portion 232-2 and the second bonding portion 231-2. The third wiring portion 232-3 and the third bonding portion 231-3 are arranged in the second direction L2, and a gap 24 having at least one corner is formed between the third wiring portion 232-3 and the third bonding portion 231-3. The fourth wiring portion 232-4 and the fourth bonding portion 231-4 are arranged in the second direction L2, and a gap 24 having at least one corner is formed between the fourth wiring portion 232-4 and the fourth bonding portion 231-4. The fifth wiring portion 232-5 and the fifth bonding portion 221-5 are arranged in the second direction L2, and a gap 24 having at least one corner is formed between the fifth wiring portion 232-5 and the fifth bonding portion 221-5. Specifically, each of the gaps 24 in the present embodiment is formed with a W shape, but the present disclosure is not limited thereto.

The five LED chips 4 are respectively mounted on the first bonding portion 231-1, the second bonding portion 231-2, the third bonding portion 231-3, the fourth bonding portion 231-4, and the fifth bonding portion 221-5, and the five LED chips 4 are respectively and electrically connected to the first wiring portion 211-1, the second wiring portion 232-2, the third wiring portion 232-3, the fourth wiring portion 232-4, and the fifth wiring portion 232-5 by wires. Moreover, the five Zener chips 5 are respectively mounted on the first bonding portion 231-1, the second bonding portion 231-2, the third bonding portion 231-3, the fourth bonding portion 231-4, and the fifth bonding portion 221-5, and the five Zener chips 5 are respectively and electrically connected to the first wiring portion 211-1, the second wiring portion 232-2, the third wiring portion 232-3, the fourth wiring portion 232-4, and the fifth wiring portion 232-5 by wires.

It should be noted that each of the bonding portions 221, 231 or each of the wiring portions 211, 232 in the present embodiment can be regarded as a functional portion 221, 231, 211, 232. That is to say, the functional portions 221, 231, 211, 232 in the present embodiment are a plurality of bonding portions 221, 231 for respectively mounting the light-emitting units U and a plurality of wiring portions 211, 232 for respectively wiring the light-emitting units U.

In addition, the number of the third metallic pads 23 of the electrode layer 2 can be adjusted according to the number of the LED chips 4. For example, as shown in FIG. 11B, the LED package structure 100 includes two LED chips 4, so that the electrode layer 2 of the LED package structure 100 includes the first metallic pad 21, the second metallic pad 22, and a single third metallic pad 23 arranged between the first metallic pad 21 and the second metallic pad 22. The structure and connection relationships of the components of the electrode layer 2 as shown in FIG. 11B are similar to those of the corresponding components of the electrode layer 2 as shown in FIG. 11A.

Specifically, as shown in FIG. 11B, the wiring portion 211 of the first metallic pad 21 can be defined as a first wiring portion 211-1. The wiring portion 232 of the third metallic pad 23 can be defined as a second wiring portion 232-2. The bonding portion 231 of the third metallic pad 23 can be defined as a first bonding portion 231-1. The bonding portion 221 of the second metallic pad 22 can be defined as a second bonding portion 221-2.

The first wiring portion 211-1 and the first bonding portion 231-1 are arranged in the second direction L2, and a gap 24 having at least one corner is formed between the first wiring portion 211-1 and the first bonding portion 231-1. The second wiring portion 232-2 and the second bonding portion 221-2 are arranged in the second direction L2, and a gap 24 having at least one corner is formed between the second wiring portion 232-2 and the second bonding portion 221-2.

The two LED chips 4 are respectively mounted on the first bonding portion 231-1 and the second bonding portion 221-2, and the two LED chips 4 are respectively and electrically connected to the first wiring portion 211-1 and the second wiring portion 232-2 by wires. Moreover, the two Zener chips 5 are respectively mounted on the first bonding portion 231-1 and the second bonding portion 221-2, and the two Zener chips 5 are respectively and electrically connected to the first wiring portion 211-1 and the second wiring portion 232-2 by wires.

In other words, each of the first metallic pad 21 and the second metallic pad 22 has an L-shaped functional portion 211-1, 221-2, and the third metallic pad 23 has a functional portion composed of two L-shaped segments 231-1, 232-2. The two L-shaped segments 231-1, 232-2 are connected to each other and are arranged in 180 degrees rotation, such that the at least one corner is formed between the two gaps 24. The functional portions of the first, second, third electrode layers 21, 22, 23 are served as a plurality of bonding portions for respectively mounting the two light-emitting units U and a plurality of wiring portions for respectively wiring the two light-emitting units U.

Specifically, the two Zener chips 5 are respectively mounted on the first bonding portion 231-1 of the third metallic pad 23 and the second bonding portion 221-2 of the second metallic pad 22. One of the two Zener chips 5 is mounted on a part of one of the two L-shaped segments 231-1 connected to the other L-shaped segment 232-2.

Moreover, as shown in FIG. 11C, which shows the LED package structure 100 that only one LED chip 4 is disposed thereon. Thus, the electrode layer 2 is provided without any third metallic pad 23. Specifically, the electrode layer 2 includes the first metallic pad 21 and the second metallic pad 22 arranged adjacent to the first metallic pad 21. The LED chip 4 is mounted on the bonding portion 221 of the second metallic pad 22 and is electrically connected to the wiring portion 211 of the first metallic pad 21 by a wire. The Zener chip 5 is mounted on the bonding portion 221 of the second metallic pad 22 and is arranged adjacent to a corner of the L-shaped wiring portion 211, and the Zener chip 5 is electrically connected to the wiring portion 211 of the first metallic pad 21 by a wire. The structure and connection relationships of the components of the electrode layer 2 as shown in FIG. 11C are similar to those of the corresponding components of the electrode layer 2 as shown in FIG. 11A.

As shown in FIGS. 9 and 10, the insulating layer 8 is disposed on the first surface 11 of the substrate 1. The insulating layer 8 is shape-complementary to and coplanar with the electrode layer 2. That is to say, the insulating layer 8 is disposed on a portion of the first surface 11 of the substrate 1 where the electrode layer 2 is not disposed, and a side edge of the insulating layer 8 is aligned with a side edge of the substrate 1.

The soldering layer 3 is disposed on the second surface 12 of the substrate 1 and is electrically connected to the electrode layer 2 and the LED chips 4. The soldering layer 3 includes a plurality of sets of soldering pads 31. The sets of the soldering pads 31 are respectively and electrically connected to the bonding portions 231, 221 and the wiring portions 211, 232 of the electrode layer 2 by using the conductive pillars 13 embedded in the substrate 1.

Specifically, each set of the soldering pads 31 includes a negative soldering pad 311 and a positive soldering pad 312. The negative soldering pads 311 of the soldering layer 3 are respectively arranged under the bonding portions 231, 221, and are respectively and electrically connected to the bonding portions 231, 221 by using the conductive pillars 13. The positive soldering pads 312 of the soldering layer 3 are respectively arranged under the wiring portions 211, 232, and are respectively and electrically connected to the wiring portions 211, 232 by using the conductive pillars 13.

Thus, the LED chips 4 can be electrically connected in series by the arrangement of the electrode layer 2. Each set of the soldering pads 31 of the soldering layer 3 is provided in an electrically independent arrangement, so that each set of the soldering pads 31 can be used to control the corresponding LED chip 4 independently. That is to say, each LED chip 4 can be independently controlled by using the corresponding set of the soldering pads 31 for being applied to an adaptive front lighting system (AFS).

Each LED chip 4 used in the present embodiment is a vertical chip. The LED chips 4 are respectively mounted on the bonding portions 221, 231 of the electrode layer 2, and are respectively and electrically connected to the wiring portions 211, 232 of the electrode layer 2 by wires. At least three side edges of each of the LED chips 4 are aligned with at least three edges of the corresponding bonding portion 221, 231.

As shown in FIGS. 9, 12, and 13, the phosphor plate 6 in the present embodiment can be phosphor in glass (PiG) or phosphor in ceramic (PiC). A top surface of the LED chip 4 is substantially covered by the phosphor plate 6, and at least one side edge of the phosphor plate 6 protrudes from the LED chip 4 at a distance D1 in a range of 5 μm˜10 μm. The phosphor plate 6 has a light emitting surface 61 arranged away from the LED chip 4. Specifically, the phosphor plate 6 in the present embodiment has at least three side edges, which respectively protrude from the three side edges of the LED chip 4 aligned with the outer edge of the corresponding bonding portion 221, 231. The light-emitting unit U in the present embodiment preferably includes a transparent adhesive layer G for bonding the phosphor plate 6 to the LED chip 4.

As shown in FIGS. 9 and 10, the Zener chips 5 are respectively mounted on the bonding portions 221, 231 of the electrode layer 2, and are respectively and electrically connected to the wiring portions 211, 232 of the electrode layer 2 by wires. The LED chip 4 and the Zener chip 5 are mounted on the same bonding portion 211, 231 and arranged on two different locations, thereby preventing a bonding gel from overflowing.

As shown in FIGS. 9, 12, and 13, the reflective housing 9 is disposed on the electrode layer 2 and the insulating layer 8. The reflective housing 9 and the insulating layer 8 in the present embodiment are integrally formed as one piece, but the present disclosure is not limited thereto. The reflective housing 9 surrounds and covers the side surfaces of each light-emitting unit U (i.e., the side surfaces of each LED chip 4 and the side surfaces of each phosphor plate 6), and the Zener chips 5 are embedded in the reflective housing 9, thereby preventing the Zener chips 5 from blocking light generated from the LED chips 4. The reflective housing 9 has a plurality of openings 92 recessed in a top plane 91 thereof so as to respectively expose the light emitting surfaces 61 of the phosphor plates 6. The side surfaces of the phosphor plate 6 are preferably flushed with a plurality of inner walls of the reflective housing 9 defining the corresponding opening 92. A plurality of side edges of the light emitting surface 61 of the phosphor plate 6 is preferably flushed with the inner walls of the reflective housing 9 that defines the corresponding opening 92.

Specifically, a distance D2 between the top plane 91 of the reflective housing 9 and the first surface 11 of the substrate 1 is larger than a distance D3 between the light emitting surface 61 of each phosphor plate 6 and the first surface 11 of the substrate 1. A distance D4 between the top plane 91 of the reflective housing 9 and the light emitting surface 61 of each phosphor plate 6 is substantially in a range of 10 μm˜30 μm.

Moreover, a portion of the reflective housing 9 arranged between any two adjacent light-emitting units U is defined as a spacer 93 having an inverted T-shaped cross-section. A lower portion of the spacer 93 arranged adjacent to the insulating layer 8 has a width W1, which is larger than a width W2 of an upper portion of the spacer 93 arranged away from the insulating layer 8. In other words, the light-emitting unit U also has a T-shaped cross-section.

Thus, the reflective housing 9 is provided with the spacers 93 formed between the any two adjacent light-emitting units U, and the top plane 91 of the reflective housing 9 is higher than the light emitting surface 61 of each phosphor 6 at 10 μm˜30 μm, so that an interference of any two adjacent light-emitting units U can be avoided for effectively increasing a light performance of the LED package structure 100. Moreover, each spacer 93 of the reflective housing 9 is an inverted T-shaped structure, which has a narrow upper portion and a wide lower portion, and each opening 92 of the reflective housing 9 in shape corresponds to the phosphor plate 6, so that a blue light leakage problem of the LED package structure 100 can be avoided.

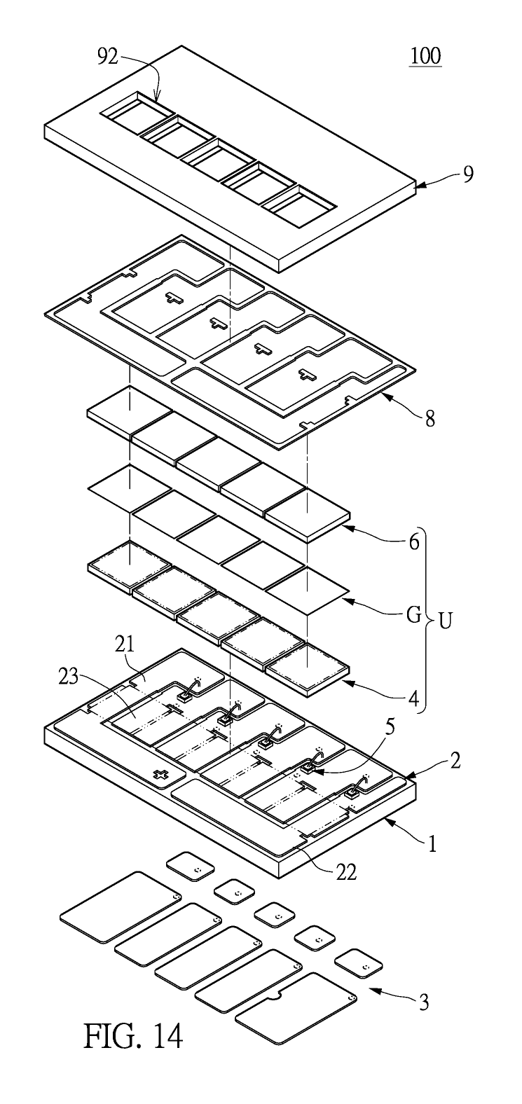

In addition, the LED package structure 100 in the present embodiment is shown as FIGS. 8 to 10, but it is not limited thereto. For example, the LED chip 4 of the LED package structure 100 can be a flip chip as shown in FIG. 14, or the number of the LED chip 4 of the LED package structure 100 can be only one (as shown in FIG. 11C and FIGS. 16 to 18) or two (as shown in FIG. 11B). Moreover, other components of the LED package structure 100, such as Zener chip 5, can be adjusted according to the number of the LED chip 4.

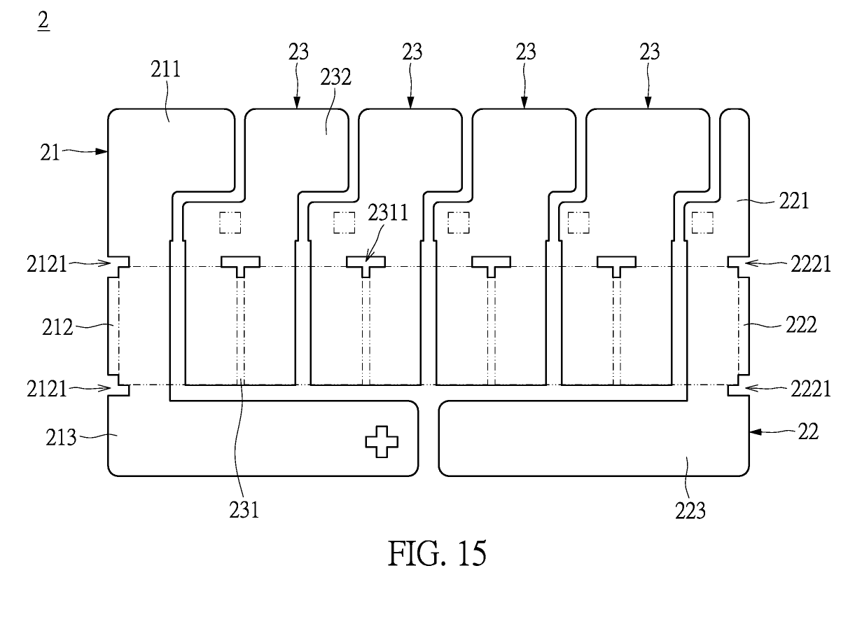

As shown in FIG. 15, the electrode layer 2 includes a first metallic pad 21, a second metallic pad 22, and four third metallic pads 23 arranged between the first metallic pad 21 and the second metallic pad 22. The first metallic pad 21 has an L-shaped functional portion 211, a rectangular first extending portion 212, and a rectangular first electrode portion 213. The second metallic pad 22 has an L-shaped functional portion 221, a rectangular second extending portion 222, and a rectangular second electrode portion 223. The two functional portions 211, 221 are provided for bonding or wiring. Each of the first extending portion 212 and the second extending portion 222 has two L-shaped slots 2121, 2221. The third metallic pads 23 each has a substantial S-shape, and the third metallic pads 23 are spaced apart from each other. An upper portion of each third metallic pad 23 is defined as a wiring portion 232 for wiring one of the Zener chips 5, and a lower portion of each third metallic pad 23 is defined as a bonding portion 231 for mounting one of the LED chips 4 and one of the Zener chips 5. The lower portion of each third metallic pad 23 further has a T-shaped slot 2311. It should be noted that each of the LED chips 4 in the present embodiment as shown in FIGS. 14 and 15 is flipped on two adjacent metallic pads 21, 22, 23. Specifically, the first LED chip 4 counted from the left side of FIG. 14 is flipped on the first metallic pad 21 and the adjacent third metallic pad 23. Each of the second, third, and fourth LED chips 4 is flipped on any two adjacent third metallic pads 23. The fifth LED chip 4 is straddled on the second metallic pad 22 and the adjacent third metallic pad 23. The L-shaped slots 2121, 2221 and the T-shaped slots 2311 are provided for positioning the LED chips 4.

The descriptions illustrated supra set forth simply the preferred embodiments of the present disclosure; however, the characteristics of the present disclosure are by no means restricted thereto. All changes, alterations, or modifications conveniently considered by those skilled in the art are deemed to be encompassed within the scope of the present disclosure delineated by the following claims.

What is claimed is:

1. An LED package structure, comprising:
a substrate having a first surface and a second surface opposite to the first surface;
an electrode layer disposed on the first surface of the substrate;
an insulating layer disposed on the first surface of the substrate, wherein the insulating layer is shape-complementary to and coplanar with the electrode layer;
at least one light-emitting unit including an LED chip and a phosphor plate adhered to the LED chip, wherein the LED chip is mounted on the electrode layer and the insulating layer, and a top surface of the LED chip is substantially covered by the phosphor plate;
a reflective housing disposed on the electrode layer and the insulating layer, wherein the reflective housing surrounds and covers side surfaces of the LED chip and side surfaces of the phosphor plate, wherein the reflective housing has at least one opening recessed in a top plane thereof so as to expose a light emitting surface of the phosphor plate, a distance between the top plane of the reflective housing and the first surface of the substrate is larger than a distance between the light emitting surface of the phosphor plate and the first surface of the substrate, and a distance between the top plane of the reflective housing and the light emitting surface of the phosphor plate is in a range of 10 μm˜30 μm; and
a soldering layer disposed on the second surface of the substrate and electrically connected to the electrode layer and the LED chip.

2. The LED package structure as claimed in claim 1, wherein the side surfaces of the phosphor plate are flushed with a plurality of inner walls of the reflective housing that defines the at least one opening.

3. The LED package structure as claimed in claim 2, wherein a plurality of side edges of the light emitting surface of the phosphor plate are flushed with the inner walls of the reflective housing that defines the at least one opening.

4. The LED package structure as claimed in claim 1, wherein at least two light-emitting units of the LED package structure are disposed on the circuit layer and the insulating layer, a portion of the reflective housing arranged between any two adjacent light-emitting units is defined as a spacer having an inverted T-shaped cross-section, and a lower portion of the spacer arranged adjacent to the insulating layer has a width larger than a width of an upper portion of the spacer arranged away from the insulating layer.

5. The LED package structure as claimed in claim 1, wherein the electrode layer includes a first metallic pad at least comprising an L-shaped wiring portion and a second metallic pad at least comprising an L-shaped bonding portion, and the LED chip is mounted on the L-shaped bonding portion of the second metallic pad and is electrically connected to the L-shaped wiring portion of the first metallic pad by a wire.

6. The LED package structure as claimed in claim 5, further comprising a Zener chip mounted on the L-shaped bonding portion of the second metallic pad, wherein the Zener chip is arranged adjacent to a corner of the L-shaped wiring portion of the second metallic pad.

7. The LED package structure as claimed in claim 1, wherein at least two light-emitting units of the LED package structure are disposed on the circuit layer and the insulating layer, the electrode layer includes a first metallic pad, a second metallic pad, and at least one third metallic pad arranged between the first metallic pad and the second metallic pad, wherein the first metallic pad, the second metallic pad, and the at least one third metallic pad are spaced apart from each other to form at least two gaps each having at least one corner, each of the first metallic pad and the second metallic pad has an L-shaped functional portion, the at least one third metallic pad has a functional portion composed of two L-shaped segments, the two L-shaped segments being connected to each other and being arranged in 180 degrees rotation, such that the at least one corner being formed between the at least two gaps, and wherein the functional portions of the first electrode layer, the second electrode layer, and the at least one third electrode layer are served as a plurality of bonding portions for the at least two light-emitting units being mounted thereon and a plurality of wiring portions for the at least two light-emitting units wiring.

8. The LED package structure as claimed in claim 7, further comprising at least one Zener chip mounted on the functional portion of the at least one third metallic pad, wherein the at least one Zener chip is mounted on a part of one of the two L-shaped segments connected to the other L-shaped segment.

9. The LED package structure as claimed in claim 1, wherein the at least one light-emitting unit includes a transparent adhesive layer configured to adhere the phosphor plate onto the LED chip.

10. The LED package structure as claimed in claim 9, wherein the transparent adhesive layer is made of a transparent silicone resin and has a thickness smaller than or equal to 10 μm.

11. The LED package structure as claimed in claim 1, wherein at least one side edge of the phosphor plate protrudes from the LED chip at a distance in a range of 5 μm˜10 μm.

12. The LED package structure as claimed in claim 7, wherein at least three side edges of each of the LED chips are aligned with at least three side edges of the corresponding bonding portion.

13. A method for manufacturing an LED package structure, comprising:
providing a substrate;
respectively disposing an electrode layer and a soldering layer on two opposite surfaces of the substrate;
mounting at least one LED chip on the electrode layer;
electrically connecting the at least one LED chip to the electrode layer and the soldering layer;
adhering at least one phosphor plate set on the at least one LED chip, wherein the at least one phosphor plate set includes a phosphor plate and a buffer sheet detachably disposed on the phosphor plate, and side surfaces of the buffer sheet are substantially and respectively aligned with that of the phosphor plate;
forming an insulating layer and a reflective housing on the substrate, wherein the insulating layer is shaped-complementary to and coplanar with the electrode layer, the reflective housing is disposed on the electrode layer and the insulating layer, and the reflective housing surrounds and covers side surfaces of the LED chip, side surfaces of the phosphor plate, and side surfaces of the buffer sheet; and
removing the buffer sheet from the phosphor plate so as to form at least one opening recessed on a top surface of the reflective housing, such that a light-emitting surface of the phosphor plate being exposed.

14. The method as claimed in claim 13, wherein the step of removing the buffer sheet from the phosphor plate further includes:
adhering a tape to the buffer sheet, wherein an adhesion between the tape and the buffer sheet is larger than an adhesion between the buffer sheet and the phosphor plate; and
tearing away the tape to remove the buffer sheet adhered on the tape from the phosphor plate.

15. The method as claimed in claim 14, wherein the step of removing the buffer sheet from the phosphor plate further includes: heating the buffer sheet.

16. The method as claimed in claim 14, wherein the step of removing the buffer sheet from the phosphor plate further includes: irradiating a UV light on the buffer sheet.

17. The method as claimed in claim 14, wherein the step of removing the buffer sheet from the phosphor plate further includes: moistening the buffer sheet by an organic solution to reduce the adhesion between the buffer sheet and the phosphor plate.

18. The method as claimed in claim 13, further comprising:
disposing the substrate in a cavity of a mold;
pressing the buffer sheet through the mold; and
injection molding an insulating material into the cavity to form the insulating layer and the reflective housing on the substrate, wherein the buffer sheet is pressed by the mold having a pressing thickness in a range of 10 μm˜30 μm.

19. The method as claimed in claim 13, wherein the buffer sheet is a thermal release tape, a heat-resistant tape, or a UV tape.

20. A phosphor plate assembly, comprising:
a carrier; and
a plurality of phosphor plate sets substantially in a matrix arrangement and detachably adhered to the carrier, each of the phosphor plate sets including:
a phosphor plate; and
a buffer sheet detachably disposed on the phosphor plate, wherein side surfaces of the buffer sheet are respectively aligned with side surfaces of the phosphor plate.
